(19) United States
(12) Patent Application Publication
(10) Pub. No.: US 2025/0151483 A1
(43) Pub. Date: May 8, 2025

(54) DISPLAY DEVICE

(71) Applicant: LG Display Co., Ltd., Seoul (KR)

(72) Inventors: Jae Kwang LEE, Paju-si (KR); Bung Goo KIM, Paju-si (KR); Hyoung Ho AHN, Paju-si (KR); Hee Won LEE, Paju-si (KR); Jun Young JO, Paju-si (KR); Hye Sun JUNG, Paju-si (KR); Sang Hak SHIN, Paju-si (KR); Hyoung Sun PARK, Paju-si (KR); Pyung Ho CHOI, Paju-si (KR); Tae Yoon KIM, Paju-si (KR)

(73) Assignee: LG Display Co., Ltd., Seoul (KR)

(21) Appl. No.: 18/789,984

(22) Filed: Jul. 31, 2024

(30) Foreign Application Priority Data
Nov. 6, 2023 (KR) 10-2023-0151506

(51) Int. Cl. H01L 33/58; H01L 25/16

(52) U.S. Cl. CPC H10H 20/855; H01L 25/167

(57) ABSTRACT

A display device includes a substrate; a plurality of light-emitting elements arranged in each of a plurality of transfer areas on the substrate; and a black matrix having a plurality of transmissive holes each corresponding to one of the plurality of light-emitting elements, wherein the plurality of transfer areas include a first transfer area and a second transfer area arranged adjacent to each other, the black matrix includes a first area corresponding to the first transfer area and a second area corresponding to the second transfer area, the first area and the second area are arranged adjacent to each other based on a virtual boundary line, the first area includes a first transmissive hole disposed at a first distance from the virtual boundary line and a second transmissive hole disposed at a second distance from the virtual boundary line, and a size of the first transmissive hole is larger than a size of the second transmissive hole.

### CROSS-REFERENCE TO RELATED APPLICATION

This application claims the priority of Korean Patent Application No. 10-2023-0151506, filed on Nov. 6, 2023, which is hereby incorporated by reference in its entirety.

### BACKGROUND

### Field of the Disclosure

The present disclosure relates to a display device.

### Description of the Background

An electroluminescent display device includes an organic light emitting display device in which an organic light emitting diode (OLED) is disposed, and an inorganic light emitting display device (hereinafter referred to as “LED display device”) in which an inorganic light emitting diode (hereinafter referred to as “LED”) is disposed.

Since the electroluminescent display device displays an image using a self-luminous element, it does not require a separate light source, such as a backlight unit, and may be implemented in thin and diverse forms.

Recently, as an example of the inorganic light emitting display device, a micro LED display device in which micro LEDs are arranged in pixels has been attracting attention as a next-generation display device. The micro LED may be an inorganic LED with a size of 100 μm or less. The micro LED is manufactured through a separate semiconductor process, and may be disposed in each sub-pixel for each color by being transferred to a pixel position on a display panel substrate of a display device.

The micro LED transfer process may be performed for each pre-divided transfer area. For example, in the transfer process of transferring micro LEDs to a panel, a plurality of micro LEDs may be transferred for each divided transfer area. At this time, the transfer process may be performed sequentially or simultaneously for a plurality of transfer areas. Here, the unit of a plurality of micro LEDs transferred to one of the plurality of transfer areas may be referred to as a stamp.

That is, the display panel may include the plurality of transfer areas for the transfer process, and one stamp may be transferred corresponding to one transfer area.

### SUMMARY

The present disclosure is to provide a display panel and a display device including the same that prevent or minimize the possibility of stains depending on a side viewing angle by arranging black matrix transmissive holes of different sizes based on a virtual boundary line (BL).

The present disclosure is also to provide a display panel and a display device including the same in which the size of a transmissive hole far from the virtual boundary line (BL) is reduced in consideration of reflection visibility.

Further, the present disclosure is to provide a display panel with improved design freedom and a display device including the same by presenting various aspects in which the size and interval of transmissive holes of a black matrix are adjusted.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a display device includes a substrate; a plurality of light-emitting elements arranged in each of a plurality of transfer areas on the substrate; and a black matrix having a plurality of transmissive holes each corresponding to one of the plurality of light-emitting elements, wherein the plurality of transfer areas include a first transfer area and a second transfer area arranged adjacent to each other, the black matrix includes a first area corresponding to the first transfer area and a second area corresponding to the second transfer area, the first area and the second area are arranged adjacent to each other based on a virtual boundary line, the first area includes a first transmissive hole disposed at a first distance from the virtual boundary line and a second transmissive hole disposed at a second distance from the virtual boundary line, and a size of the first transmissive hole is larger than a size of the second transmissive hole.

In another aspect of the present disclosure, a display device includes a substrate; a plurality of light-emitting elements arranged in each of a plurality of transfer areas on the substrate; and a black matrix having a plurality of transmissive holes each corresponding to one of the plurality of light-emitting elements, wherein the plurality of transfer areas include a first transfer area and a second transfer area arranged adjacent to each other based on a virtual boundary line, the black matrix includes a first area corresponding to the first transfer area and a second area corresponding to the second transfer area, and the transmissive holes arranged in the first area have a size that becomes smaller as a distance from the virtual boundary line increases.

According to the present disclosure, the possibility of occurrence of stains depending on the side viewing angle may be prevented or minimized by forming the area of the first transmissive hole arranged along the virtual boundary line to be larger than the other transmissive holes. Thus, the display device according to the present disclosure may enable low-power driving by improving the display quality at the side viewing angle without separate compensation for the luminance difference.

According to the present disclosure, the reflection visibility at the side viewing angle may be reduced by reducing the size of the transmissive hole far from the virtual boundary line. Therefore, the display quality of the display device according to the present disclosure may be improved.

According to the present disclosure, the design freedom of the display device may be improved by adjusting the size and interval of the transmissive holes of the black matrix.

Various useful advantages and effects of the present disclosure are not limited to the above-described contents and will be more easily understood from descriptions of the specific aspects.

### BRIEF DESCRIPTION OF THE DRAWINGS

The above and other features and advantages of the present disclosure will become more apparent to those of ordinary skill in the art by describing exemplary aspects thereof in detail with reference to the attached drawings, in which:

FIG. 1 is a diagram showing a display device according to an aspect of the present disclosure;

FIG. 2 is an enlarged view showing area A of FIG. 1;

FIG. 3 is a diagram showing a partial area of a pixel;

FIG. 4 is a cross-sectional view taken along line I-I′ in FIG. 3;

FIG. 5 is a cross-sectional view taken along line II-II′ in FIG. 3;

FIG. 6 is a cross-sectional view taken along line III-III′ in FIG. 3;

FIG. 7 is a cross-sectional view showing an example in which a main light-emitting element and a sub-light-emitting element are electrically connected to a pixel driving circuit;

FIG. 8 is a diagram showing a display device according to another aspect of the present disclosure;

FIG. 9 is a cross-sectional view taken along line IV-IV′ in FIG. 8.

FIG. 10 is a diagram showing the first comparative example regarding transfer areas and an arrangement relationship between a light-emitting element disposed in the transfer area and a black matrix;

FIG. 11 is a diagram showing the second comparative example regarding transfer areas and an arrangement relationship between a light-emitting element disposed in the transfer area and a black matrix;

FIG. 12 is a diagram briefly showing a cross-section of the comparative example shown in FIG. 11;

FIG. 13 is a graph showing the emission of light detected at a side viewing angle in the first and second comparative examples;

FIG. 14 is a diagram showing an arrangement relationship between a light-emitting element and a black matrix in a display device according to the first aspect;

FIG. 15 is a diagram briefly showing a cross-section taken along line V-V′ of FIG. 14;

FIG. 16 is a diagram showing a first example of an arrangement relationship between a light-emitting element and a black matrix in a display device according to the second aspect;

FIG. 17 is a diagram showing a second example of an arrangement relationship between a light-emitting element and a black matrix in a display device according to the second aspect;

FIG. 18 is a diagram showing a black matrix of a display device according to the second aspect;

FIG. 19 is a diagram showing a first area of a black matrix of a display device according to the second aspect;

FIG. 20 is a diagram briefly showing a cross-section taken along line VI-VI′ of FIG. 17;

FIG. 21 is a graph showing the emission of light detected at a side viewing angle in the first and second examples of the second aspect;

FIG. 22 is a graph showing the luminance of a display device according to the comparative example and the luminance of a display device according to the second aspect;

FIG. 23 is a diagram showing an arrangement relationship between a light-emitting element and a black matrix in a display device according to the third aspect;

FIG. 24 is a diagram showing a black matrix of a display device according to the third aspect; and

FIG. 25 is a diagram showing a first area of a black matrix of a display device according to the third aspect.

### DETAILED DESCRIPTION

The advantages and features of the present disclosure and methods for accomplishing the same will be more clearly understood from aspects described below with reference to the accompanying drawings. However, the present disclosure is not limited to the following aspects, but may be implemented in various different forms; rather, the present aspects will make the disclosure of the present disclosure complete and allow those skilled in the art to fully comprehend the scope of the present disclosure.

Shapes, sizes, ratios, angles, numbers, and the like disclosed in the drawings for describing the aspects of the present disclosure are exemplary, and the present disclosure is not limited to the illustrated items. Like reference numerals refer to like elements throughout. In addition, in describing the present disclosure, if it is determined that the detailed description of the related known technology may unnecessarily obscure the subject matter of the present disclosure, the detailed description thereof will be omitted.

The terms such as “comprising”, “including”, “having” and “consisting of” used herein are generally intended to allow other components to be added unless the terms are used with the term “only”. References to the singular shall be construed to include the plural unless expressly stated otherwise.

In interpreting a component, it is interpreted to include an error range even if there is no separate description.

When describing a positional or interconnected relationship between two components, such as “on top of”, “above”, “below”, “next to”, “connect or couple with”, “crossing”, “intersecting” etc., one or more other components may be interposed between them unless “immediately” or “directly” is used.

When describing a temporal contextual relationship is described, such as “after”, “following”, “next to” or “before”, it may not be continuous on a time scale unless “immediately” or “directly” is used.

The terms “first”, “second” and the like may be used to distinguish components from each other, but the functions or structures of the components are not limited by ordinal numbers or component names in front of the components.

The following aspects may be combined or associated with each other in whole or in part, and various types of interlocking and driving are technically possible. The aspects may be implemented independently of each other or together in an interrelated relationship.

Hereinafter, preferred aspects of the present disclosure will be described in detail with reference to the accompanying drawings.

A display device according to an aspect of the present disclosure includes a display panel where a display area or screen on which an image is displayed is disposed, and a pixel driving circuit that drives pixels of the display panel. The display area includes a pixel area where pixels are arranged. The pixel area includes a plurality of light emitting areas. A light-emitting element is disposed in each of the light emitting areas. The pixel driving circuit may be embedded in the display panel.

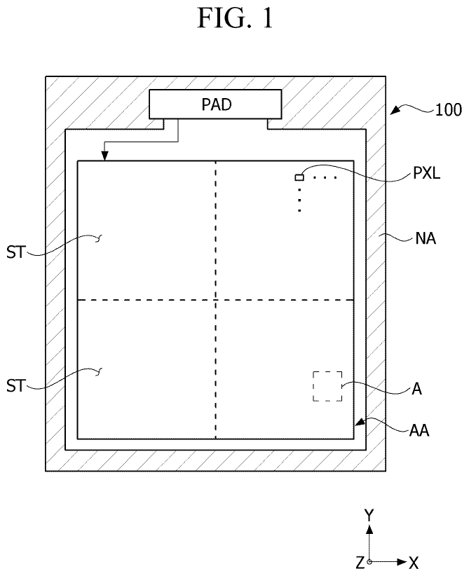

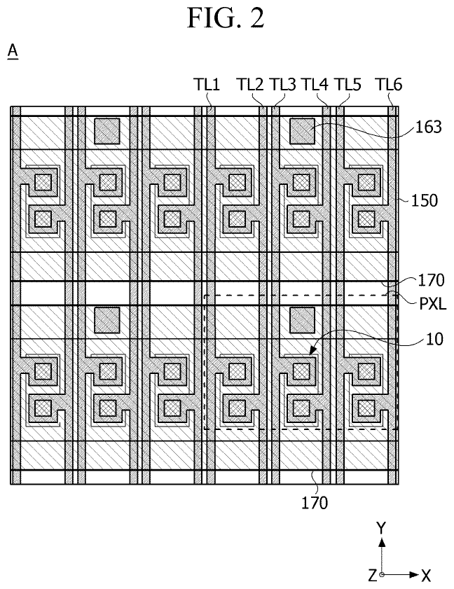

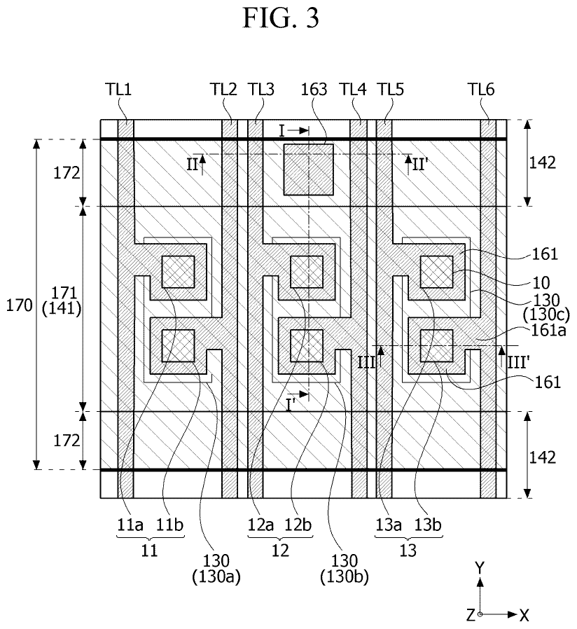

FIG. 1 is a diagram showing a display device according to an aspect of the present disclosure. FIG. 2 is an enlarged view showing area A of FIG. 1. FIG. 3 is a diagram showing a partial area of a pixel.

Referring to FIGS. 1 and 2, the display device 100 according to an aspect of the present disclosure includes a display panel that visually reproduces an input image. The display panel may include a display area AA where an image is displayed, and a non-display area NA where the image is not displayed. In the non-display area NA, various wires and a driving circuit may be mounted, and a pad portion PAD to which integrated circuits, printed circuits, etc. are connected may be disposed. Here, the display panel may be a panel with a rectangular structure having a width in the X-axis direction, a length in the Y-axis direction, and a thickness in the Z-axis direction. At this time, the width and length of the display panel may be set to various design values depending on the application field of the display device. In addition, the X-axis direction may refer to the width direction, row direction, or horizontal direction, the Y-axis direction may refer to the length direction, column direction, or vertical direction, and the Z-axis direction may refer to the height direction or thickness direction. Also, the X-axis direction, the Y-axis direction, and the Z-axis direction may be perpendicular to each other, but they may also refer to different directions that are not perpendicular to each other. Accordingly, each of the X-axis direction, the Y-axis direction, and the Z-axis direction may be described as any one of a first direction, a second direction, and a third direction. And, a surface extending in the X-axis direction and the Y-axis direction may refer to a horizontal surface.

A plurality of light-emitting elements 10 disposed in the display area AA and forming a pixel PXL may be micro-sized inorganic light-emitting elements. The inorganic light-emitting elements may be grown on a silicon wafer and then attached to the display panel through a transfer process.

The transfer process of the light-emitting elements 10 may be performed for each pre-divided area. Although the display area AA is divided into four transfer areas ST in FIG. 1, the size or number of divisions of the transfer areas is not limited to this. The transfer process may be performed sequentially or simultaneously in the first to ninth transfer areas ST. In each transfer area ST, a blue light-emitting element 10, a green light-emitting element 10, and a red light-emitting element 10 may be sequentially transferred.

In the non-display area NA, a data driving circuit or a gate driving circuit may be disposed, and wires through which control signals for controlling these driving circuits are supplied may be disposed. Here, the control signal includes various timing signals such as a clock signal, an input data enable signal, and a synchronization signal, and it may be received through the pad portion PAD.

The pixels PXL may be driven by a pixel driving circuit. The pixel driving circuit may drive a plurality of pixels by receiving a driving voltage, an image signal (digital signal), a synchronization signal synchronized with the image signal, etc., and outputting an anode voltage and a cathode voltage of the light-emitting element 10. The driving voltage may be a high potential voltage (EVDD). The cathode voltage may be a low potential voltage (EVSS) commonly applied to the pixels. The anode voltage may be a voltage corresponding to a pixel data value of the image signal. The pixel driving circuit may be disposed in the non-display area NA or below the display area AA.

Each of the pixels PXL may include a plurality of sub-pixels having different colors. For example, the plurality of pixels may include a red sub-pixel in which the light-emitting element 10 that emits light in a red wavelength is disposed, a green sub-pixel in which the light-emitting clement 10 that emits light in a green wavelength is disposed, and a blue sub-pixel in which the light-emitting element 10 that emits light in a blue wavelength is disposed. The plurality of pixels may further include white pixels.

Referring to FIGS. 2 and 3, the plurality of pixels PXL may be sequentially arranged in the first direction (X-axis direction) and the second direction (Y-axis direction). In the pixel of the display area AA, a plurality of sub-pixels of the same color may be arranged. For example, each of the plurality of pixels may include a first red sub-pixel in which a first-first light-emitting element 11a that emits light in a red wavelength is disposed, a second red sub-pixel in which a first-second light-emitting element 11b that emits light in a red wavelength is disposed, a first green sub-pixel in which a second-first light-emitting element 12a that emits light in a green wavelength is disposed, a second green sub-pixel in which a second-second light-emitting element 12b that emits light in a green wavelength is disposed, a first blue sub-pixel in which a third-first light-emitting element 13a that emits light in a blue wavelength is disposed, and a second blue sub-pixel in which a third-second light-emitting element 13b that emits light in a blue wavelength is disposed. The first-first light-emitting element 11a, the second-first light-emitting element 12a, and the third-first light-emitting element 13a may be interpreted as main light-emitting elements. The first-second light-emitting element 11b, the second-second light-emitting element 12b, and the third-second light-emitting element 13b may be interpreted as sub-light-emitting elements.

One sub-pixel includes at least one light-emitting element, and if one light-emitting clement becomes defective, the brightness of the sub-pixel may be adjusted by increasing the brightness of the other light-emitting elements. However, it is not necessarily limited to this, and one sub-pixel may include only one light-emitting element.

A plurality of first electrodes 161 are each disposed under the light-emitting element 10 and may be selectively connected to a plurality of signal wires TL1 to TL6 through an extension portion 161a. A high potential voltage may be applied to the pixel driving circuit through the signal wires TL to TL6. The signal wires TL to TL6 and the first electrode 161 may be formed as an integrated electrode pattern during an electrode patterning process.

Exemplarily, a first signal wire TL1 may be connected to the anode electrode of the first red sub-pixel, and a second signal wire TL2 may be connected to the anode electrode of the second red sub-pixel. A third signal wire TL3 may be connected to the anode electrode of the first green sub-pixel, and a fourth signal wire TL4 may be connected to the anode electrode of the second green sub-pixel. A fifth signal wire TL5 may be connected to the anode electrode of the first blue sub-pixel, and a sixth signal wire TL6 may be connected to the anode electrode of the second blue sub-pixel. If one sub-pixel includes only one light-emitting element, the number of signal wires TL may be reduced by half.

A second electrode 170 may be a cathode electrode that is disposed in each row and applies a cathode voltage to the light-emitting elements 10 continuously arranged in the first direction (X-axis direction). The plurality of second electrodes 170 may be arranged to be spaced apart from each other in the second direction (Y-axis direction). The plurality of second electrodes 170 may be connected to the cathode voltage through a contact electrode 163. Each of the plurality of second electrodes 170 may be electrically connected to the contact electrode 163. However, it is not necessarily limited to this, and the second electrode 170 may not be divided into plural pieces but may be composed of one electrode layer to function as a common electrode.

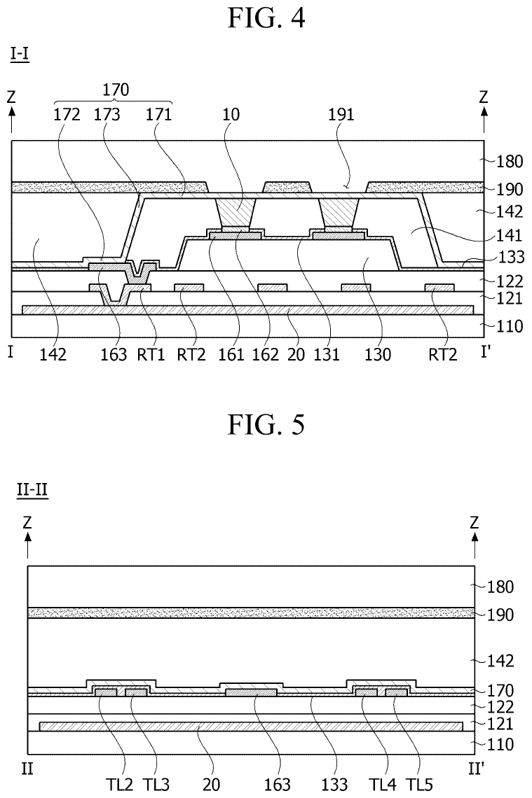

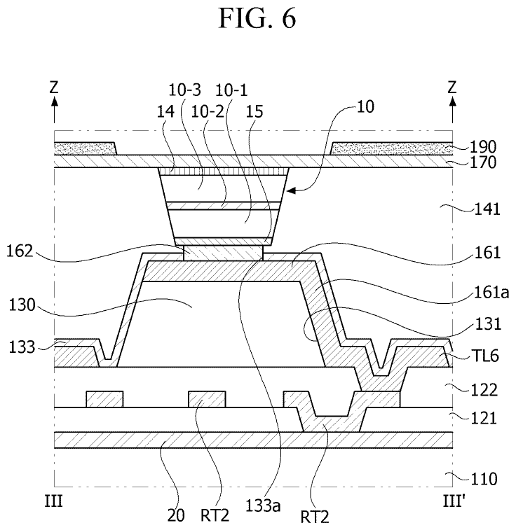

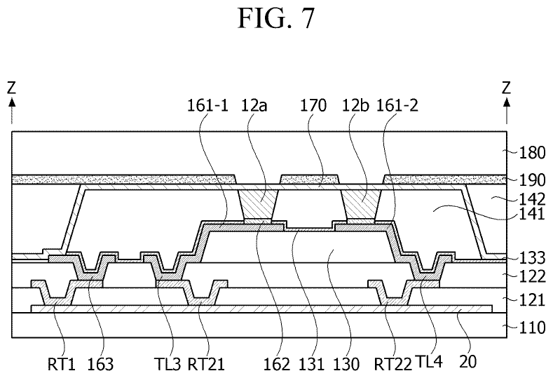

FIG. 4 is a cross-sectional view taken along line I-I′ in FIG. 3. FIG. 5 is a cross-sectional view taken along line II-II′ in FIG. 3. FIG. 6 is a cross-sectional view taken along line III-III′ in FIG. 3. FIG. 7 is a cross-sectional view showing an example in which two light-emitting elements are electrically connected to a pixel driving circuit.

Referring to FIGS. 3 to 5, the display device according to an aspect includes a plurality of first electrodes 161 and contact electrodes 163 disposed on a substrate 110, a plurality of light-emitting elements 10 disposed on the plurality of first electrodes 161, a first optical layer 141 disposed between the plurality of light-emitting elements 10, and a second electrode 170 disposed on the plurality of light-emitting elements 10.

The substrate 110 may be made of plastic with flexibility. For example, the substrate 110 may be manufactured as a single-layer or multi-layer substrate of a material selected from, but is not limited to, polyimide, polyethylene terephthalate, polyethylene naphthalate, polycarbonate, polyethersulfone, polyarylate, polysulfone, and cyclic-olefin copolymer. For example, the substrate 110 may be a ceramic substrate or a glass substrate.

A pixel driving circuit 20 may be disposed in the display area AA on the substrate 110. The pixel driving circuit 20 may include a plurality of thin film transistors using an amorphous silicon semiconductor, a polycrystalline silicon semiconductor, or an oxide semiconductor.

The pixel driving circuit 20 may include at least one driving thin film transistor, at least one switching thin film transistor, and at least one storage capacitor. When the pixel driving circuit 20 includes a plurality of thin film transistors, it may be formed on the substrate 110 through a thin film transistor (TFT) manufacturing process. In an aspect, the pixel driving circuit 20 may be a general term for the plurality of thin film transistors electrically connected to the light-emitting element 10.

The pixel driving circuit 20 may be a driving driver manufactured on a single crystal semiconductor substrate 110 using a metal-oxide-silicon field effect transistor (MOSFET) manufacturing process. The driving driver may include a plurality of pixel driving circuits to drive a plurality of sub-pixels. When the pixel driving circuit 20 is implemented as the driving driver, after an adhesive layer is disposed on the substrate 110, the driving driver may be mounted on the adhesive layer through a transfer process.

A buffer layer 121 may be disposed on the substrate 110 to cover the pixel driving circuit 20. The buffer layer 121 may be made of an organic insulating material, for example, but is not limited to, photosensitive photo acryl or photosensitive polyimide.

The buffer layer 121 may include an inorganic insulating material, for example, silicon nitride (SiNx) or silicon oxide (SiO₂), stacked in a multi-layer manner, or an organic insulating material and an inorganic insulating material stacked in a multi-layer manner.

An insulating layer 122 may be disposed on the buffer layer 121. The insulating layer 122 may be made of an organic insulating material, for example, but is not limited to, photosensitive photo acryl or photosensitive polyimide. Connection wires RT1 and RT2 may be disposed on the buffer layer 121. The connection wires RT1 and RT2 may be connected to the corresponding signal wires TL1 to TL6. The connection wires RT1 and RT2 may include a plurality of wire patterns arranged on different layers with one or more insulating layers interposed therebetween. The wire patterns arranged on different layers may be electrically connected through a contact hole penetrating the insulating layer.

A plurality of bank patterns 130 may be disposed on the insulating layer 122. At least one light-emitting element 10 may be disposed on each bank pattern 130. For example, a first light-emitting clement 11 may be disposed on a first bank pattern 130a, a second light-emitting element 12 may be disposed on a second bank pattern 130b, and a third light-emitting element 13 may be disposed on a third bank pattern 130c.

The bank pattern 130 may be made of an organic insulating material, for example, but is not limited to, photosensitive photo acryl or photosensitive polyimide. The bank pattern 130 may guide the location where the light-emitting element 10 will be attached during the transfer process of the light-emitting element 10. The bank pattern 130 may be omitted.

A solder pattern 162 may be disposed on the first electrode 161. The solder pattern 162 may be made of, but is not limited to, indium (In), tin (Sn), or an alloy thereof.

The plurality of light-emitting elements 10 may each be mounted on the solder pattern 162. One pixel may include the light-emitting elements 10 of three colors. The first light-emitting clement 11 may be a red light-emitting element, the second light-emitting element 12 may be a green light-emitting element, and the third light-emitting element 13 may be a blue light-emitting element. Two light emitting elements may be mounted in each sub-pixel.

The first optical layer 141 may cover the plurality of light-emitting elements 10 and the bank pattern 130. Therefore, the first optical layer 141 may cover between the plurality of light-emitting elements 10 and between the plurality of bank patterns 130. The first optical layer 141 extends in the first direction (X) and is arranged to be spaced apart in the second direction (Y) to separate pixels arranged to be spaced apart in the second direction. Accordingly, the first optical layer 141 may be separated between pixel rows. Here, the row may refer to the first direction. Additionally, one pixel row consisting of a plurality of pixels arranged along the first direction may be called a pixel group. Therefore, the display panel may include a plurality of pixel groups arranged to be spaced apart from each other in the second direction. For example, because the first optical layer 141 arranged along the first direction is disposed around the pixels, and the plurality of first optical layers 141 disposed corresponding to the plurality of pixel groups are spaced apart from each other in the second direction, one first optical layer 141 disposed around the pixels forming one row may be separated from the other first optical layer 141 disposed around the pixels forming another row.

The first optical layer 141 may include an organic insulating material in which fine metal particles such as titanium dioxide particles are dispersed. Light emitted from the plurality of light-emitting elements 10 may be scattered by fine metal particles dispersed in the first optical layer 141 and emitted to the outside.

The second electrode 170 may be disposed on the plurality of light-emitting elements 10. The second electrode 170 may be commonly connected to the plurality of pixels PXL. The second electrode 170 may be a thin electrode that transmits light. The second electrode 170 may be a transparent electrode material, for example, but is not limited to, indium tin oxide (ITO).

The second electrode 170 may extend in the first direction (X-axis direction) and be spaced apart in the second direction (Y-axis direction). For example, one second electrode 170 may be formed to extend in the first direction, and a plurality of second electrodes 170 extending in the first direction may be arranged to be spaced apart from each other along the second direction. At this time, the second electrode 170 may be arranged to correspond to each of the pixels arranged to be spaced apart from each other in the second direction. The second electrode 170 may include a first region 171 disposed on the upper surface of the light-emitting element 10 and the upper surface of the first optical layer 141, a second region 172 being in contact with and electrically connected to the contact electrode 163, and a third region 173 disposed on the side of the first optical layer 141 and connecting the first region 171 and the second region 172.

In a plan view, the plurality of second electrodes 170 may each overlap with the first optical layer 141, and the third region 173 may cover the outer plane of the first optical layer 141.

A second optical layer 142 may be an organic insulating material surrounding the first optical layer 141. The second optical layer 142 may be disposed on the insulating layer 122 together with the first optical layer 141. The first optical layer 141 and the second optical layer 142 may include the same material (e.g., siloxane). For example, the first optical layer 141 may be siloxane that contains titanium oxide (TiOₓ), and the second optical layer 142 may be siloxane that does not contain titanium oxide (TiOₓ). However, it is not necessarily limited to this, and the first optical layer 141 and the second optical layer 142 may be formed of the same material or may be formed of different materials.

According to an aspect, the second region 172 of the second electrode 170 is connected to the contact electrode 163 in an overall flat state, so excessive stress is not concentrated at the connection point with the contact electrode 163. Therefore, cracks may be effectively prevented from occurring in the second electrode 170.

The second optical layer 142 may cover the second and third regions 172 and 173 of the second electrode 170. The upper surface of the second optical layer 142 and the upper surface of the first region 171 of the second electrode 170 may be coplanar. That is, the first region 171 and the second optical layer 142 may function as a planarization layer. Due to this, there is no step on the surface where a black matrix 190 is formed, so a pattern of the black matrix 190 may be easily formed on the first optical layer 141 and the second optical layer 142. However, it is not necessarily limited to this, and the upper surfaces of the second optical layer 142 and the second electrode 170 may have different heights.

The black matrix 190 may be an organic insulating material to which black pigment is added. The second electrode 170 may be in contact with the contact electrode 163 under the black matrix 190. A transmission hole 191 through which light emitted from the light-emitting element 10 is output to the outside may be formed between the patterns of the black matrix 190. The transmission hole 191 may overlap with the light-emitting element 10 in the Z-axis direction, and a partial area of the black matrix 190 may overlap with the first optical layer 141 in the Z-axis direction. Here, the Z-axis direction may be called the third direction. Therefore, the black matrix 190 may improve the problem in which light emitted from each of neighboring light-emitting elements 10 is mixed by the first optical layer 141 and then emitted.

A cover layer 180 may be an organic insulating material that covers the black matrix 190 and the second electrode 170. In FIGS. 2 and 3, the black matrix 190 and the cover layer 180 are omitted.

The contact electrode 163 may be electrically connected to the first connection wire RT1 disposed thereunder, and the first connection wire RT1 may be connected to the pixel driving circuit 20. Therefore, the cathode voltage may be applied to the second electrode 170 through the contact electrode 163. The first electrode 161 may be electrically connected to the second connection wire RT2. This will be described later.

Referring to FIG. 5, the contact electrode 163 and signal wires TL1 to TL6 may be disposed on the same plane. The pixel driving circuit 20 may be disposed under the contact electrode 163 and the signal wires TL1 to TL6. When the pixel driving circuit 20 is a driving driver, a plurality of driving drivers may be disposed within the display panel.

A passivation layer 133 may expose the contact electrode 163 so that the contact electrode 163 and the second electrode 170 are electrically connected. In addition, the passivation layer 133 may insulate the signal wires TL2 to TL5 and the second electrode 170. Here, the passivation layer 133 may be formed of an inorganic material.

Referring to FIG. 6, the connection portion 161a of the first electrode 161 may extend to one side 131 of the bank pattern 130 and be electrically connected to the connection wire RT2 disposed on the buffer layer 121.

The first electrode 161, the connection portion 161a, the signal wires TL, and/or the connection wires RT1 and RT2 may include a single or multi-layer metal layer of one of titanium (Ti), molybdenum (Mo), and aluminum (Al).

The passivation layer 133 is disposed on the first electrode 161 and the signal wire TL and may have an opening hole 133a exposing the solder pattern 162. Here, the opening hole 133a exposing the solder pattern 162 may be referred to as a first opening hole.

The light-emitting element 10 may include a first conductive semiconductor layer 10-1, an active layer 10-2 disposed on the first conductive semiconductor layer 10-1, and a second conductive semiconductor layer 10-3 disposed on the active layer 10-2. A first driving electrode 15 may be disposed under the first conductive semiconductor layer 10-1, and a second driving electrode 14 may be disposed on the second conductive semiconductor layer 10-3.

The light-emitting element 10 may be formed on a silicon wafer using a method such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering.

The first conductivity semiconductor layer 10-1 may be implemented with compound semiconductor such as group III-V or group II-VI and doped with a first dopant. The first conductive semiconductor layer 10-1 may be formed of, but is not limited to, one or more of a semiconductor material with a composition formula of Alₓ₁In_{y1}Ga_{(1-x1-y1)}N (0≤x1≤1, 0≤y1≤1, 0≤x1+y1≤1), InAlGaN, AlGaAs, GaP, GaAs, GaAsP, or AlGaInP. When the first dopant is an n-type dopant such as Si, Ge, Sn, Se, or Te, the first conductive semiconductor layer 10-1 may be an n-type nitride semiconductor layer. However, when the first dopant is a p-type dopant, the first conductive semiconductor layer 10-1 may be a p-type nitride semiconductor layer.

The active layer 10-2 is a layer where electrons (or holes) injected through the first conductive semiconductor layer 10-1 and holes (or electrons) injected through the second conductive semiconductor layer 10-3 meet. The active layer 10-2 transitions to a low energy level as electrons and holes recombine, thus generating light with a corresponding wavelength.

The active layer 10-2 may have any one of a single well structure, a multi-well structure, a single quantum well structure, a multi quantum well (MQW) structure, a quantum dot structure, or a quantum wire structure, but the structure of the active layer 10-2 is not limited to this. The active layer 10-2 may generate light in the visible light wavelength range. By way of example, the active layer 10-2 may output light in any one of blue, green, and red wavelength bands.

The second conductive semiconductor layer 10-3 may be disposed on the active layer 10-2. The second conductive semiconductor layer 10-3 may be implemented with a compound semiconductor such as group III-V or group II-VI and doped with a second dopant. The second conductive semiconductor layer 10-3 may be formed of a semiconductor material with a composition formula of Inₓ₂Al_{y2}Ga_{1-x2-y2}N (0≤x2≤1, 0≤y2≤1, 0≤x2+y2≤1) or a material selected from AlInN, AlGaAs, GaP, GaAs, GaAsP, or AlGaInP. When the second dopant is a p-type dopant such as Mg, Zn, Ca, Sr, or Ba, the second conductive semiconductor layer 10-3 doped with the second dopant may be a p-type semiconductor layer. When the second dopant is an n-type dopant, the second conductive semiconductor layer 10-3 may be an n-type nitride semiconductor layer.

Although the aspect describes a vertical structure in which the driving electrodes 14 and 15 are disposed on and under the light emitting structure, the light-emitting element may have a lateral structure or a flip chip structure rather than the vertical structure.

Referring to FIG. 7, a main light-emitting element 12a and a sub-light-emitting element 12b of the sub-pixel may be disposed on the bank pattern 130. The second light-emitting element 12 will be described by way of example. A first-first electrode 161-1 connected to the main light-emitting element 12a may extend to one side of the bank pattern 130 and be electrically connected to a second-first connection wire RT21 disposed thereunder. A first-second electrode 161-2 connected to the sub-light-emitting element 12b may extend to the other side of the bank pattern 130 and be electrically connected to a second-second connection wire RT22 disposed thereunder.

The pixel driving circuit 20 may apply an anode voltage to the main light-emitting element 12a through the second-first connection wire RT21, and apply an anode voltage to the sub-light-emitting element 12b through the second-second connection wire RT22. The pixel driving circuit 20 may apply a cathode voltage to the main light-emitting clement 12a and the sub-light-emitting element 12b through the first connection wire RT1 and the second electrode 170.

The pixel driving circuit 20 may adjust luminance by driving only the main light-emitting element 12a or by simultaneously driving the main light-emitting element 12a and the sub-light-emitting element 12b. If the main light emitting element 12a is darkened, the luminance may be adjusted by driving only the sub-light-emitting element 12b.

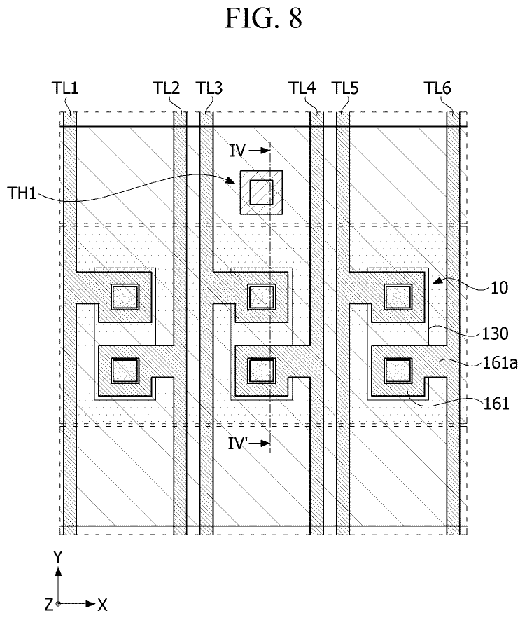

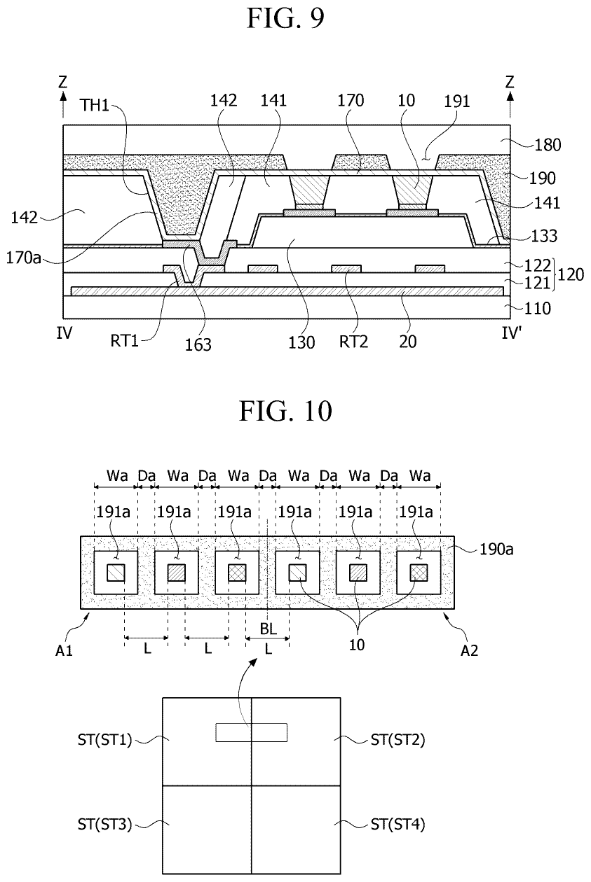

FIG. 8 is a diagram showing a display device according to another aspect of the present disclosure. FIG. 9 is a cross-sectional view taken along line IV-IV′ in FIG. 8.

Referring to FIGS. 8 and 9, the second electrode 170 may be electrically connected to the contact electrode 163 through a contact hole TH1 formed in the second optical layer 142. The second optical layer 142 may have the contact hole TH1 exposing the contact electrode 163. The second electrode 170 inserted into the contact hole TH1 of the second optical layer 142 may be in contact with the upper surface of the contact electrode 163. The contact hole TH1 may be formed in an outer area of the pixel.

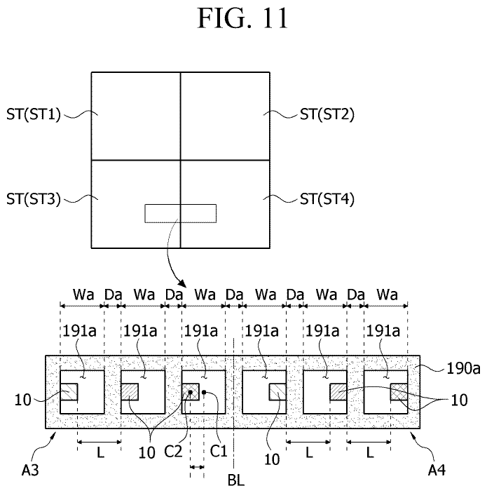

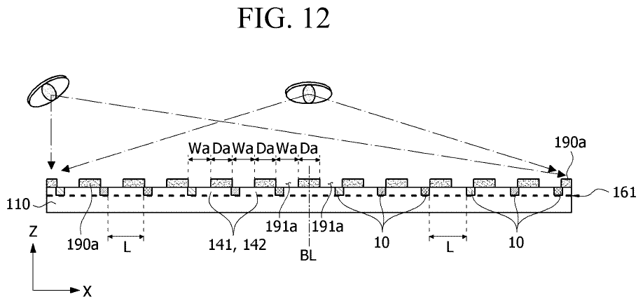

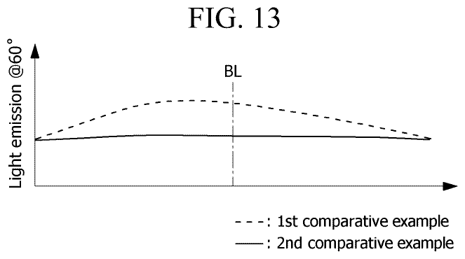

FIG. 10 is a diagram showing the first comparative example regarding transfer areas and an arrangement relationship between a light-emitting element disposed in the transfer area and a black matrix, and FIG. 11 is a diagram showing the second comparative example regarding transfer areas and an arrangement relationship between a light-emitting element disposed in the transfer area and a black matrix. FIG. 12 is a diagram briefly showing a cross-section of the comparative example shown in FIG. 11, and FIG. 13 is a graph showing the emission of light detected at a side viewing angle in the first and second comparative examples.

Referring to FIGS. 10 and 11, the display device according to the comparative example may include a plurality of light-emitting elements 10 arranged in each transfer area ST, and a black matrix 190a having a plurality of transmissive holes 191a corresponding to the light-emitting elements 10, respectively. Here, the transmissive hole 191a may be formed in, but is not limited to, a square shape in a plan view. For example, the transmissive hole 191a may be formed in various shapes such as a circular shape or a polygonal shape in a plan view. In each transfer area ST, the plurality of light-emitting elements 10 may be continuously arranged in the first direction (X-axis direction) and the second direction (Y-axis direction).

As the transfer process is performed for each pre-divided area, the display device according to the comparative example may include the plurality of transfer areas ST. For example, the display device according to the comparative example may include a first transfer area ST1, a second transfer area ST2, a third transfer area ST3, and a fourth transfer area ST4.

For each of the plurality of transfer areas ST, a virtual boundary may be formed. Therefore, two transfer areas ST arranged adjacent to each other may be partitioned based on the boundary. As shown in FIGS. 10 and 11, a square-shaped line representing one transfer area ST may indicate the boundary, and one side of one boundary may be shared with another boundary, but it is not necessarily limited to this. For example, when the boundary is formed in a rectangular shape and the transfer areas are arranged in a T-shape, one side of one boundary may be shared with two boundaries.

The plurality of light-emitting elements 10 may be disposed in each of the transfer areas ST, and the light-emitting elements 10 may be arranged in one transfer area ST to have a predetermined distance L. For example, the first light-emitting element, the second light-emitting element, the third light-emitting element, and the Nth light-emitting element disposed on a horizontal plane of one transfer area ST may have the same separation distance. Here, the separation distance between the light-emitting elements 10 may be referred to as a light-emitting element distance.

The black matrix 190a may be formed through a single process and may have the plurality of transmissive holes 191a each formed to correspond to each of the light-emitting elements 10 disposed in all transfer areas ST. At this time, all the transmissive holes 191a may be the same size. For example, the area occupied by each transmissive hole 191a on the horizontal plane of the black matrix 190a may be the same, and the width Wa may also be the same. Additionally, the interval Da between all the transmissive holes 191a may be the same. Here, the interval between the transmissive holes 191a may be referred to as a hole interval.

In addition, the black matrix 190a may include a plurality of areas corresponding to the transfer areas ST, respectively. For example, the black matrix 190a may include a first area A1 corresponding to the first transfer area ST1, a second area A2 corresponding to the second transfer area ST2, a third area A3 corresponding to the third transfer area ST3, and a fourth area A4 corresponding to the fourth transfer area ST4.

As each area of the black matrix 190a corresponds to each transfer area ST, the black matrix 190a may include a virtual boundary line BL for defining each area. For example, the virtual boundary line BL may be disposed between the first area A1 and the second area A2, so that the first area A1 and the second area A2 may be placed adjacent to each other based on the virtual boundary line BL. Also, the other side of the first area A1 may be placed opposite to the third area A3 based on another virtual boundary line BL.

However, since the transfer process is performed for each transfer area ST, a transfer tolerance may occur between the light-emitting elements 10 disposed respectively in two adjacent transfer areas ST. Referring to FIG. 11, as the center C1 of the transmissive hole 191a and the center C2 of the light-emitting element 10 are arranged to be spaced apart at a predetermined interval, an offset may be formed between the center C1 of the transmissive hole 191a and the center C2 of the light-emitting element 10.

In the comparative example, the distance L between the light-emitting elements 10 for each transfer area ST is the same, and the interval Da and area between all the transmissive holes 191a disposed in the black matrix 190a are the same. Therefore, when a transfer tolerance occurs in at least one transfer area ST, the distance between two light-emitting elements 10 arranged opposite to each other based on the virtual boundary line BL is different from the distance between the light-emitting elements 10 arranged in one area. Additionally, a portion of one of the two light-emitting elements 10 arranged opposite to each other based on the virtual boundary line BL may overlap with the black matrix 190a, thereby reducing light emission efficiency. Accordingly, a luminance difference may occur between adjacent areas based on the virtual boundary line BL, and this luminance difference may cause stains near the virtual boundary line BL.

Referring to FIG. 12, the possibility of such stain occurring may vary depending on the viewing angle at which the display device is viewed, and the possibility of seeing the stain increases at a side viewing angle of approximately 60 degrees toward the display device. For example, the luminance difference detected at the front viewing angle may be compensated based on location, but in the case of the side viewing angle, since the luminance difference may be detected differently depending on the viewing angle, it is difficult to perform compensation according to the viewing angle. Accordingly, stains at the side viewing angle may deteriorate the display quality of the display device. Here, FIG. 12 simply shows the arrangement relationship of the display device including the substrate 110, the first electrode 161 disposed on the substrate 110, the light-emitting element 10 disposed on the first electrode 161, the optical layers 141 and 142 disposed around the light-emitting element 10, and the black matrix 190a having the plurality of transmissive holes 191a corresponding to the light-emitting elements 10.

Referring to FIG. 13, in the case of a display device in which a transfer tolerance does not occur as in the first comparative example, it may be seen that there is almost no luminance difference based on the virtual boundary line BL when the display device is viewed from a side viewing angle. However, in the case of a display device in which a transfer tolerance occurs as in the second comparative example, it may be seen that a luminance difference occurs based on the virtual boundary line BL that separates the transfer areas arranged adjacent to each other. Therefore, when the display device is viewed from a side viewing angle, the possibility of seeing stains near the virtual boundary line BL increases.

Referring to the comparative example, the luminance difference caused by the viewing angle occurs depending on the arrangement position of the light-emitting element 10 with respect to the virtual boundary line BL due to the transfer tolerance according to the transfer process for each transfer area, and this luminance difference may cause stains near the virtual boundary line BL

Accordingly, aspects of the present disclosure form a transmissive hole disposed adjacent to the virtual boundary line BL to be larger in size than the transmissive hole 191a of the comparative example, thereby preventing or minimizing stains that may be visible from a side viewing angle. Here, among a plurality of transmissive holes according to the aspects of the present disclosure, the transmissive hole furthest from the virtual boundary line BL may be formed to have the same size as the transmissive hole 191a of the comparative example.

Hereinafter, aspects according to the present disclosure regarding the size, position, and interval between transmissive holes arranged in one transfer area ST will be presented to provide a display device optimized for stains.

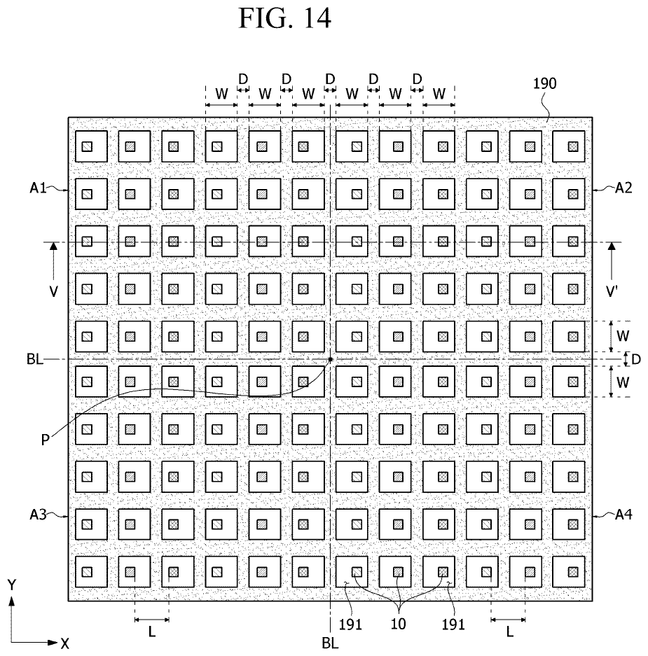

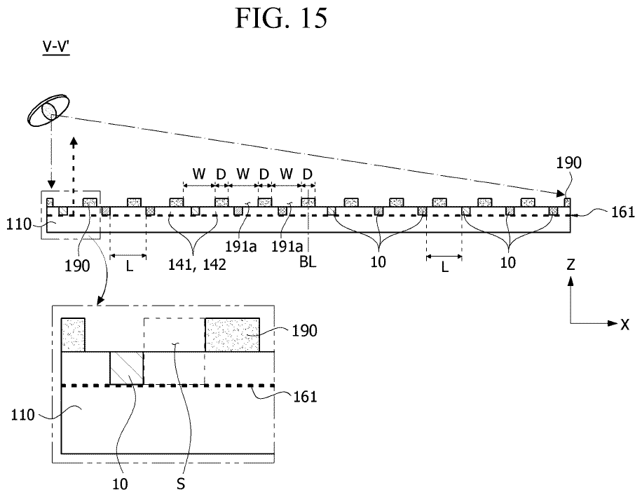

FIG. 14 is a diagram showing an arrangement relationship between a light-emitting clement and a black matrix in a display device according to the first aspect, and FIG. 15 is a diagram briefly showing a cross-section taken along line V-V′ of FIG. 14. The dotted arrow shown in FIG. 15 may represent light reflected from the first electrode 161, but it is not necessarily limited thereto. For example, In addition to the first electrode 161 in contact with the light-emitting element 10 that overlaps with a space S between the side of the transmissive hole 191 and one side of the light-emitting element 10 with respect to the horizontal plane in the third direction, which is the Z-axis direction, it may be another wire that overlaps with the space S in the third direction.

Referring to FIGS. 10, 11, 14, and 15, when comparing the display device according to the comparative example and the display device according to the first aspect, the size of the transmissive hole 191 of the display device according to the first aspect is larger than the size of the transmissive hole 191a of the display device according to the comparative example, and the distance D between the transmissive holes 191 of the display device according to the first aspect is smaller than the distance Da between the transmissive holes 191a of the display device according to the comparative example. That is, the area occupied by the transmissive hole 191 of the display device according to the first aspect in the black matrix 190 is larger than the area occupied by the transmissive hole 191a of the display device according to the comparative example in the black matrix 190a. At this time, the size of the light-emitting element 10 disposed in the transmissive hole 191 of the display device according to the first aspect may be the same as the size of the light-emitting element 10 disposed in the transmissive hole 191a of the comparative example.

Referring to FIGS. 14 and 15, the display device according to the first aspect may include a substrate 110, a first electrode 161 disposed on the substrate 110, a light-emitting element 10 disposed on the first electrode 161, optical layers 141 and 142 disposed around the light-emitting element 10, and a black matrix 190 having a plurality of transmissive holes 191 corresponding to the light-emitting elements 10. In addition, the display device according to the first aspect may include a plurality of transfer areas ST and areas of the black matrix 190 each disposed to correspond to each of the transfer areas ST.

The black matrix 190 may include a first area A1 corresponding to the first transfer area ST1, a second area A2 corresponding to the second transfer area ST2, a third area A3 corresponding to the third transfer area ST3, and a fourth area A4 corresponding to the fourth transfer area ST4.

Additionally, the black matrix 190 may include a virtual boundary line BL for defining each of the areas A1 to A4. Here, the plurality of virtual boundary lines BL disposed in the black matrix 190 may be distinguished using ordinal numbers, such as a first virtual boundary line and a second virtual boundary line.

Additionally, the transmissive holes 191 disposed in each of the areas A1 to A4 of the black matrix 190 may be arranged to be rotationally symmetric with respect to an intersection point P where the virtual boundary lines BL intersect. Also, two areas arranged adjacent to each other may be arranged to be axially symmetric with respect to the virtual boundary line BL. For example, the first area A1 and the second area A2 arranged adjacent to each other may be arranged symmetrically with respect to the virtual boundary line BL.

The transmissive holes 191 of the display device according to the first aspect may be arranged to have the same size and interval, and may have a larger size than the size of the transmissive hole 191a of the display device according to the comparative example, and a smaller interval than the interval Da between the transmissive holes 191a of the display device according to the comparative example. Here, the transmissive holes 191 of the display device according to the first aspect may be arranged to have the same width W and the same interval D. In detail, based on the X-axis direction, the width W of the transmissive hole 191 of the display device according to the first aspect may be 1.12 times the width Wa of the transmissive hole 191a of the display device according to the comparative example and be 2.57 to 2.58 times the width of the light-emitting element 10. For example, based on the X-axis direction, the width W of the transmissive hole 191 of the display device according to the first aspect may be 18 μm, the width Wa of the transmissive hole 191a of the display device according to the comparative example may be 16 μm, and the width of the light-emitting element 10 may be 7 μm.

Accordingly, even if a transfer tolerance is formed in the light-emitting clement 10 disposed in one of the transfer areas ST, the transmissive hole 191 of the display device according to the aspect, which is formed larger than the transmissive hole 191a of the comparative example, may prevent or minimize the occurrence of stains at the virtual boundary line BL based on the side viewing angle.

As the transmissive hole 191 of the display device according to the first aspect is formed larger than the transmissive hole 191a of the display device according to the comparative example, a portion of the first electrode 161 may be exposed through the transmissive hole 191. Accordingly, light flowing in through the space S between the side of the transmissive hole 191 and one side of the light-emitting element 10 may be reflected by the first electrode 161.

Since the area of the transmissive hole 191 of the display device according to the first aspect is larger than the area of the transmissive hole 191a of the comparative example, the light reflected by the first electrode 161 increases based on the side viewing angle, and this may cause the quality of the display device according to the aspect to be reduced. For example, the sensitivity of light reflected by the first electrode 161 may be referred to as reflection visibility, and the display quality at the side viewing angle may be reduced due to the reflection visibility.

Therefore, the display device according to the second aspect will be presented hereinafter regarding various design factors such as the size of the transmissive hole 191 and the interval between the transmissive holes 191 depending on the arrangement position, thereby not only preventing or minimizing the stains, but also preventing or minimizing the reflection visibility.

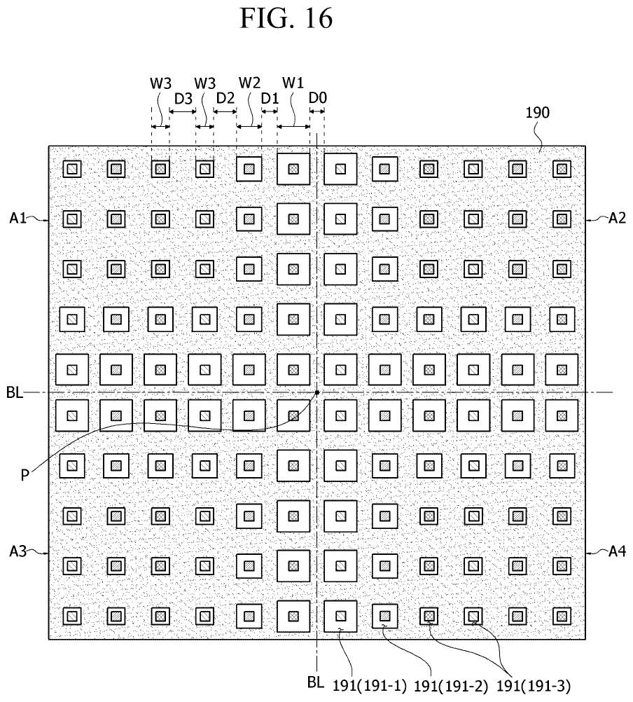

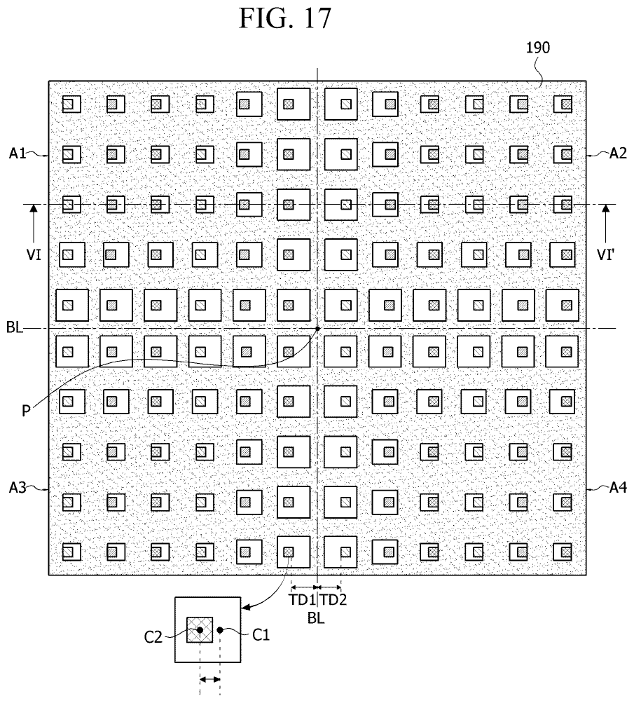

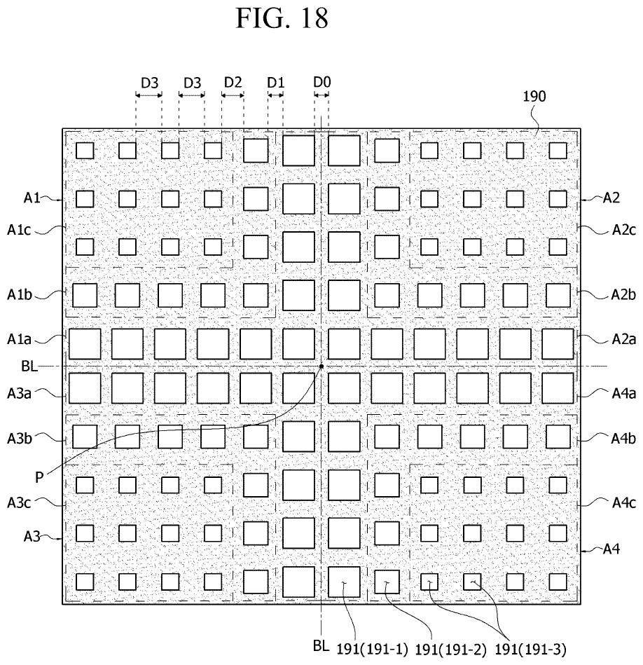

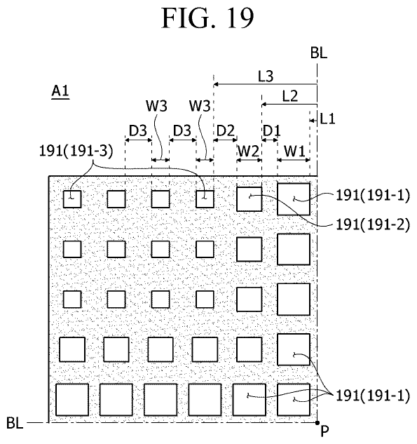

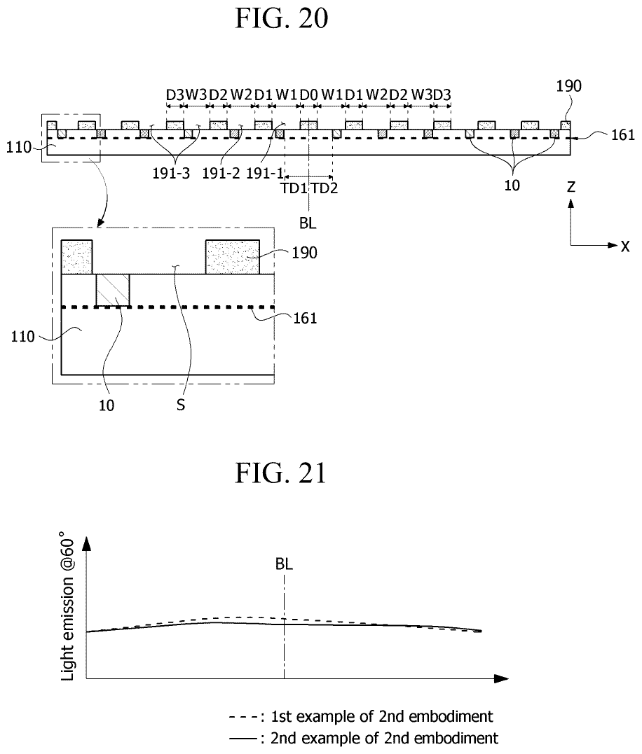

FIG. 16 is a diagram showing a first example of an arrangement relationship between a light-emitting element and a black matrix in a display device according to the second aspect, and FIG. 17 is a diagram showing a second example of an arrangement relationship between a light-emitting element and a black matrix in a display device according to the second aspect. FIG. 18 is a diagram showing a black matrix of a display device according to the second aspect, FIG. 19 is a diagram showing a first area of a black matrix of a display device according to the second aspect, and FIG. 20 is a diagram briefly showing a cross-section taken along line VI-VI′ of FIG. 17. FIG. 21 is a graph showing the emission of light detected at a side viewing angle in the first and second examples of the second aspect. Here, depending on the transfer position of the light-emitting element 10 for each transfer area, FIG. 16 shows an example of the second aspect and FIG. 17 shows another example of the second aspect. However, in the second aspect, the transfer position of the light-emitting element 10 is not limited to FIGS. 16 and 17. For example, since the transfer position of the light-emitting element 10 may be different for each transfer area, there may be various aspects of the arrangement relationship between the light-emitting element and the black matrix. However, in consideration of the possibility of stains, the display device according to the second aspect will be described by selecting one of the Normal Case with the lowest frequency of occurrence of stains and the Worst Case with the highest probability of occurrence of stains.

Referring to FIGS. 14 to 20, when comparing the display device according to the first aspect and the display device according to the second aspect, the transmissive holes 191 of the display device according to the second aspect disposed at a predetermined distance from the virtual boundary line BL are smaller than the transmissive holes 191 of the display device according to the first aspect. For example, the size of a first transmissive hole 191-1 disposed at a first distance L1 from the virtual boundary line BL may be larger than the size of a second transmissive hole 191-2 disposed at a second distance L2. Here, the second distance L2 is larger than the first distance L1.

In addition, the transmissive holes 191 of the display device according to the first aspect are formed at regular intervals D, but the transmissive holes 191 of the display device according to the second aspect are formed at different intervals depending on the distance from the virtual boundary line BL. For example, the size of the first transmissive hole 191-1 disposed at the first distance L1 from the virtual boundary line BL may be larger than the size of the second transmissive hole 191-2 disposed at the second distance L2. Here, the second distance L2 is larger than the first distance L1. At this time, the area of the transmissive hole 191-3 of the display device according to the second aspect furthest from the virtual boundary line BL may be equal to the area of the transmissive hole 191a of the comparative example. In addition, the size of the light-emitting element 10 disposed in the transmissive hole 191 of the display device according to the second aspect may be equal to the size of the light-emitting element 10 disposed in the transmissive hole 191a of the comparative example. Additionally, the light-emitting elements 10 may be arranged in one transfer area ST to have a predetermined distance L.

Referring to FIGS. 16 to 20, the display device according to the second aspect may include a substrate 110, a first electrode 161 disposed on the substrate 110, a light-emitting element 10 disposed on the first electrode 161, optical layers 141 and 142 disposed around the light-emitting element 10, and a black matrix 190 having a plurality of transmissive holes 191 corresponding to the light-emitting elements 10. In addition, the display device according to the second aspect may include a plurality of transfer areas ST and areas of the black matrix 190 each disposed to correspond to each of the transfer areas ST.

The black matrix 190 may include a first area A1 corresponding to the first transfer area ST1, a second area A2 corresponding to the second transfer area ST2, a third area A3 corresponding to the third transfer area ST3, and a fourth area A4 corresponding to the fourth transfer area ST4.

Additionally, the black matrix 190 may include a virtual boundary line BL for defining each of the areas A1 to A4. Here, the plurality of virtual boundary lines BL disposed in the black matrix 190 may be distinguished using ordinal numbers, such as a first virtual boundary line and a second virtual boundary line.

Additionally, the transmissive holes 191 disposed in each of the areas A1 to A4 of the black matrix 190 may be arranged to be rotationally symmetric with respect to an intersection point P where the virtual boundary lines BL intersect. Also, two areas arranged adjacent to each other may be arranged to be axially symmetric with respect to the virtual boundary line BL. For example, the first area A1 and the second area A2 arranged adjacent to each other may be arranged symmetrically with respect to the virtual boundary line BL.

The transmissive holes 191 of the display device according to the second aspect may be arranged to have different sizes and different intervals. At this time, each of the light-emitting elements 10 is exposed through each of the plurality of transmissive holes 191, and the light generated by the light-emitting element 10 may be irradiated to the outside through each of the plurality of transmissive holes 191.

Referring to FIGS. 18 and 19, each of the areas A1 to A4 of the black matrix 190 may have a first transmissive hole 191-1 disposed at a first distance L1 based on the virtual boundary line BL, a second transmissive hole 191-2 disposed at a second distance L2 larger than the first distance L1, and a third transmissive hole 191-3 disposed at a third distance L3 larger than the second distance L2. At this time, the first distance L1 may be, but is not limited to, the distance from the virtual boundary line BL to one side of the first transmissive hole 191-1. For example, the first distance L1 may be the distance from the virtual boundary line BL to the center C1 of the first transmissive hole 191-1. Here, the display device according to the second aspect includes three types of transmissive holes, but it is not necessarily limited thereto.

Considering the possibility of stains occurring at the side viewing angle and the reflection visibility, the size of the first transmissive hole 191-1 is larger than the size of the second transmissive hole 191-2, the size of the third transmissive hole 191-3 is smaller than the size of the second transmissive hole 191-2, and the size of the third transmissive hole 191-3 may be equal to the size of the transmissive hole 191a in the comparative example. As shown in FIG. 19, the first width W1 of the first transmissive hole 191-1 is larger than the second width W2 of the second transmissive hole 191-2, the third width W3 of the third transmissive hole 191-3 is smaller than the second width W2 of the second transmissive hole 191-2, and the third width W3 of the third transmissive hole 191-3 is equal to the width Wa of the transmissive hole 191a of the comparative example. For example, the first width W1 of the first transmissive hole 191-1 may be 18 μm, the second width W2 of the second transmissive hole 191-2 may be 17 μm, the third width W3 of the third transmissive hole 191-3 may be 16 μm, and the width of the light-emitting element 10 may be 7 μm. Accordingly, the first light-emitting clement disposed to correspond to the first transmissive hole 191-1 does not overlap with the black matrix 190 in the Z-axis direction, thereby preventing or minimizing stains detected from the side viewing angle. Here, the size of each transmissive hole 191 may represent the area on the horizontal plane of the black matrix 190.

In addition, the transmissive holes 191 of the display device according to the second aspect may be arranged to have different intervals based on the virtual boundary line BL.

The interval D0 between the first transmissive hole 191-1 in the first area A1 and the first transmissive hole 191-1 in the second area A2, which are disposed adjacent to each other, may be smaller than the first interval D1 between the first transmissive hole 191-1 and the second transmissive hole 191-2 disposed in the first area A1. Here, the interval D0 between the first transmissive hole 191-1 in the first area A1 and the first transmissive hole 191-1 in the second area A2 may be referred to as a zero^{th} interval D0. For example, the zero^{th} interval D0 may be 8 μm, and the first interval D1 may be 8.5 μm.

Additionally, the first interval D1 may be smaller than the second interval D2 between the second and third transmissive holes 191-2 and 191-3 disposed in the first area A1. For example, the second interval D2 may be 9.5 μm.

In addition, the second interval D2 may be smaller than the third interval D3 between the third transmissive holes 191-3 adjacent to each other and disposed in the first area A1. For example, the third interval D3 may be 10 μm.

That is, considering that the light-emitting elements 10 in one transfer area ST are arranged at a predetermined interval, the transmissive holes 191 vary in the area depending on the separation distance from the virtual boundary line BL, and/or the horizontal area of the transmissive hole 191 is larger than the horizontal area of the light-emitting element 10, the zero^{th} interval D0 may be smaller than the first interval D1, the first interval D1 may be smaller than the second interval D2, and the second interval D2 may be smaller than the third interval D3.

In addition, each of the areas A1 to A4 of the black matrix 190 may include, according to the distance from the virtual boundary line BL, a first unit area Aa where the first transmissive holes 191-1 are arranged, a second unit area Ab where the second transmissive holes 191-2 are arranged, and a third unit area Ac where the third transmissive holes 191-3 are arranged. For example, the first area A1 of the black matrix 190 may include, depending on the distance from the virtual boundary line BL, a first unit area A1a where the first transmissive holes 191-1 are arranged, a second unit area A1b where the second transmissive holes 191-2 are arranged, and a third unit area A1c where the third transmissive holes 191-3 are arranged. The second to fourth areas A2 to A4 may also include a plurality of unit areas.

Accordingly, the area of the transmissive holes 191 disposed in the black matrix 190 becomes smaller as the distance from the virtual boundary line BL increases, and the area may become constant from a certain distance. In addition, the interval of the transmissive holes 191 disposed in the black matrix 190 become larger as the distance from the virtual boundary line BL increases, and the interval may become constant from a certain distance.

Additionally, the first transmissive holes 191-1 may be arranged along the virtual boundary line BL, and the second transmissive holes 191-2 may be arranged along the first transmissive holes 191-1. Also, the third transmissive holes 191-3 may be arranged along the second transmissive holes 191-2, but the arrangement is not limited thereto. As shown in FIG. 19, the transmissive holes 191 that are farther away from the virtual boundary line BL by the third distance L3 or more may have the same size as the third transmissive hole 191-3.

Due to the transfer tolerance of the light-emitting elements 10 transferred for each transfer area ST, a deviation may occur between the center of the transmissive hole 191 and the center of the light-emitting element 10.

Referring to FIG. 17, as the center C1 of the transmissive hole 191 and the center C2 of the light-emitting element 10 are arranged to be spaced apart at a certain interval, an offset may be formed between the center C1 of the transmissive hole 191 and the centers C2 of the light-emitting element 10. Therefore, the distance TD1 from the light-emitting element 10 of the first transfer area ST1 exposed through the first transmissive hole 191-1 of the first area A1 to the virtual boundary line BL may be different from the distance TD2 from the light-emitting element 10 of the second transfer area ST2 exposed through the first transmissive hole 191-1 of the second area A2 to the virtual boundary line BL. At this time, both the first transmissive hole 191-1 disposed in the first area A1 and the first transmissive hole 191-1 disposed in the second area A2 are the transmissive holes 191 disposed adjacent to the virtual boundary line BL.

Here, the light-emitting element 10 of each transfer area ST exposed through the first transmissive hole 191-1 may be referred to as the first light-emitting element. Similarly, the light-emitting element 10 exposed through the second transmissive hole 191-2 may be referred to as the second light-emitting element, and the light-emitting element 10 exposed through the third transmissive hole 191-3 may be referred to as the third light-emitting element. In addition, when the display device is viewed in the Z-axis direction, the distance from the virtual boundary line BL to the first light-emitting element in the first transfer area ST1 may be referred to as the first transfer distance TD1, and the distance from the virtual boundary line BL to the first light-emitting element in the second transfer area ST2 may be referred to as the second transfer distance TD2. Accordingly, the first transfer distance TD1 and the second transfer distance TD2 may be different. Also, as the sum of the first transfer distance TD1 and the second transfer distance TD2 increases, the possibility of stains forming in the display device increases. For example, the larger the sum of the first transfer distance TD1 and the second transfer distance TD2 is than the distance from the center C1 of the first transmissive hole 191-1 disposed in the first area A1 to the center C1 of the first transmissive hole 191-1 disposed in the second area A2, the more likely it is that stains will occur.

However, the display device according to the second aspect may prevent or minimize stains detected at a side viewing angle through the first transmissive hole 191-1 having a relatively larger area than the second transmissive hole 191-2.

Referring to FIG. 21, when comparing the display device in which a transfer tolerance does not occur as in the first example, and the display device in which a transfer tolerance occurs as in the second example of the second aspect, it may be seen that there is almost no luminance difference based on the virtual boundary line BL. Thus, the black matrix 190 provided in the display device according to the second aspect may significantly reduce the possibility of stains forming near the virtual boundary line BL.

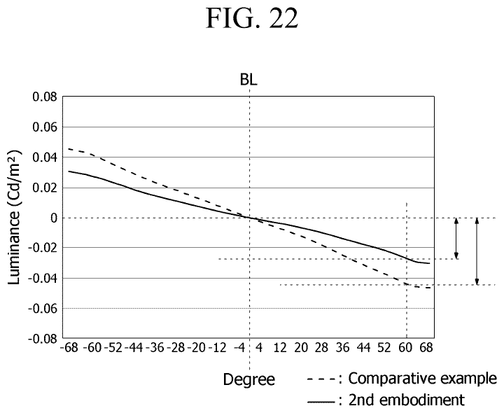

FIG. 22 is a graph showing the luminance of a display device according to the comparative example and the luminance of a display device according to the second aspect.

Referring to FIG. 22, it may be seen that the luminance of the display device according to the comparative example differs by about 4.3% at a viewing angle of 60 degrees compared to 0 degrees, and the luminance of the display device according to the second aspect differs by about 2.75% at a viewing angle of 60 degrees compared to 0 degrees. Here, FIG. 22 is shown based on values calculated by measuring luminance in the transmissive hole 191a of the display device according to the comparative example and the first transmissive hole 191-1 of the display device according to the second aspect.

Compared to the comparative example, the display device according to the second aspect may significantly reduce the possibility of occurrence of stains by reducing the luminance difference.

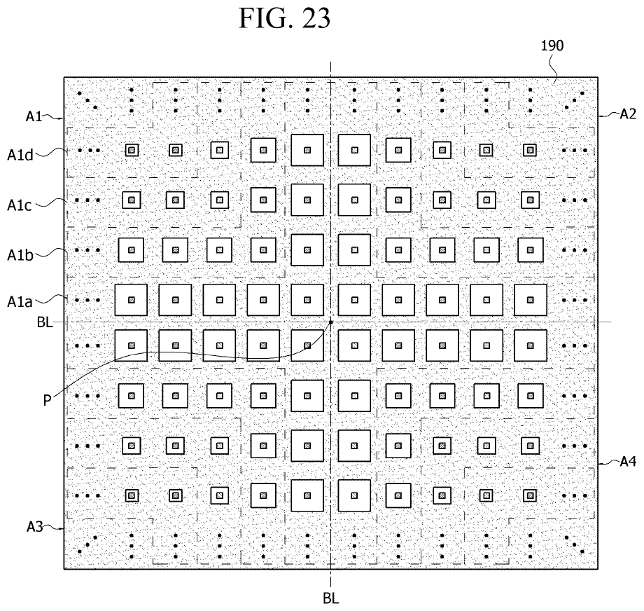

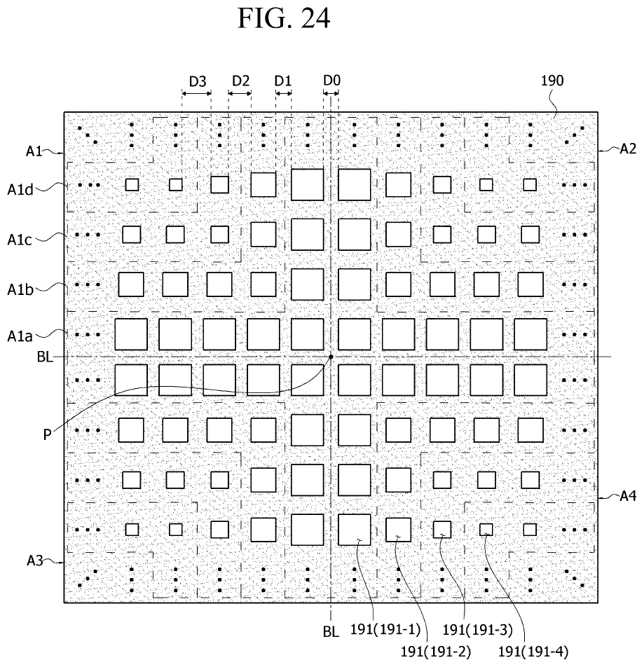

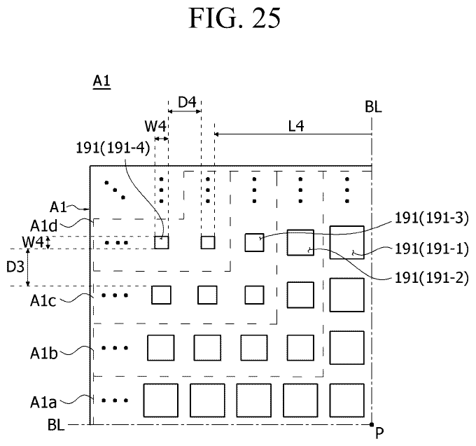

FIG. 23 is a diagram showing an arrangement relationship between a light-emitting element and a black matrix in a display device according to the third aspect, FIG. 24 is a diagram showing a black matrix of a display device according to the third aspect, and FIG. 25 is a diagram showing a first area of a black matrix of a display device according to the third aspect.

Referring to FIGS. 17 to 20 and 23 to 25, when comparing the display device according to the second aspect and the display device according to the third aspect, the transmissive holes 191 of the display device according to the third aspect are different from the transmissive holes 191 of the display device according to the second aspect in that the farther away they are from the virtual boundary line, the smaller they become in size, and the larger the interval therebetween becomes.

Referring to FIGS. 23 to 25, the display device according to the third aspect may include a substrate 110, a first electrode 161 disposed on the substrate 110, a light-emitting element 10 disposed on the first electrode 161, optical layers 141 and 142 disposed around the light-emitting element 10, and a black matrix 190 having a plurality of transmissive holes 191 corresponding to the light-emitting elements 10. In addition, the display device according to the third aspect may include a plurality of transfer areas ST and areas of the black matrix 190 each disposed to correspond to each of the transfer areas ST.

The black matrix 190 may include a first area A1 corresponding to the first transfer area ST1, a second area A2 corresponding to the second transfer area ST2, a third area A3 corresponding to the third transfer area ST3, and a fourth area A4 corresponding to the fourth transfer area ST4. Additionally, the black matrix 190 may include a virtual boundary line BL for defining each of the areas A1 to A4.

Additionally, the transmissive holes 191 disposed in each of the areas A1 to A4 of the black matrix 190 may be arranged to be rotationally symmetric with respect to an intersection point P where the virtual boundary lines BL intersect. Also, two areas arranged adjacent to each other may be arranged to be axially symmetric with respect to the virtual boundary line BL.

The transmissive holes 191 of the display device according to the third aspect may be arranged to have different sizes and different intervals. At this time, each of the light-emitting elements 10 is exposed through each of the plurality of transmissive holes 191, and the light generated by the light-emitting element 10 may be irradiated to the outside through each of the plurality of transmissive holes 191.

Referring to FIGS. 23 and 25, each of the areas A1 to A4 of the black matrix 190 may have a first transmissive hole 191-1, a second transmissive hole 191-2, a third transmissive hole 191-3, a fourth transmissive hole 191-4, and an Nth transmissive hole 191-N, which are arranged sequentially depending on the distance from the virtual boundary line BL. For example, based on the virtual boundary line BL, the first transmissive hole 191-1 may be disposed at a first distance L1, the second transmissive hole 191-2 may be disposed at a second distance L2 larger than the first distance L1, the third transmissive hole 191-3 may be disposed at a third distance L3 larger than the second distance L2, and the fourth transmissive hole 191-4 may be disposed at a fourth distance L4 larger than the third distance L3.

Considering the possibility of stains occurring at the side viewing angle and the reflection visibility, the size of the first transmissive hole 191-1 is larger than the size of the second transmissive hole 191-2, the size of the third transmissive hole 191-3 is smaller than the size of the second transmissive hole 191-2, the size of the fourth transmissive hole 191-4 is smaller than the size of the third transmissive hole 191-3, and the size of the Nth transmissive hole 191-N is equal to the size of the transmissive hole 191a in the comparative example. As shown in FIG. 25, the first width W1 of the first transmissive hole 191-1 is larger than the second width W2 of the second transmissive hole 191-2, the third width W3 of the third transmissive hole 191-3 is smaller than the width W2 of the second transmissive hole 191-2, the fourth width W4 of the fourth transmissive hole 191-4 is smaller than the width W3 of the third transmissive hole 191-3, and the width of the Nth transmissive hole 191-N may be equal to the width Wa of the transmissive hole 191a in the comparative example. For example, the first width W1 of the first transmissive hole 191-1 may be 18 μm, the second width W2 of the second transmissive hole 191-2 may be 17.9 μm, the third width W3 of the third transmissive hole 191-3 may be 17.8 μm, the fourth width W4 of the fourth transmissive hole 191-4 may be 17.7 μm, and the width of the light-emitting element 10 may be 7 μm. Accordingly, the first light-emitting element disposed to correspond to the first transmissive hole 191-1 does not overlap with the black matrix 190 in the Z-axis direction, thereby preventing or minimizing stains detected from the side viewing angle. At this time, the Nth light-emitting element 10 disposed to correspond to the Nth transmissive hole 191-N may overlap with the black matrix 190 in the Z-axis direction. Here, the size of each transmissive hole 191 may represent the area on the horizontal plane of the black matrix 190.

Additionally, the transmissive holes 191 of the display device according to the third aspect may be arranged at different intervals based on the virtual boundary line BL. For example, as the transmissive holes 191 of the display device according to the third aspect become farther away from the virtual boundary line BL, the interval between the transmissive holes 191 may increase.

The interval D0 between the first transmissive hole 191-1 in the first area A1 and the first transmissive hole 191-1 in the second area A2, which are disposed adjacent to each other, may be smaller than the first interval D1 between the first transmissive hole 191-1 and the second transmissive hole 191-2 disposed in the first area A1. Here, the interval DO between the first transmissive hole 191-1 in the first area A1 and the first transmissive hole 191-1 in the second area A2 may be referred to as a zeroth interval D0. For example, the zeroth interval D0 may be 8 μm, and the first interval D1 may be 8.1 μm.

Additionally, the first interval D1 may be smaller than the second interval D2 between the second and third transmissive holes 191-2 and 191-3 disposed in the first area A1. For example, the second interval D2 may be 8.2 μm.

In addition, the second interval D2 may be smaller than the third interval D3 between the third and fourth transmissive holes 191-3 and 191-4 adjacent to each other and disposed in the first area A1. For example, the third interval D3 may be 8.3 μm.

That is, considering that the zeroth interval D0 is smaller than the first interval D1, the first interval D1 is smaller than the second interval D2, and the second interval D2 is smaller than the third interval D3, the interval between the transmissive holes 191 may increase as the distance from the virtual boundary line BL increases. Accordingly, in the display device according to the third aspect, the interval between the transmissive holes 191 may be increased in response to the area of the transmissive hole 191 becoming smaller as the distance from the virtual boundary line BL increases.

In addition, each of the areas A1 to A4 of the black matrix 190 may include, according to the distance from the virtual boundary line BL, a first unit area Aa where the first transmissive holes 191-1 are arranged, a second unit area Ab where the second transmissive holes 191-2 are arranged, a third unit area Ac where the third transmissive holes 191-3 are arranged, a fourth unit area Ad where the fourth transmissive holes 191-4 are arranged, and an Nth unit area An where the Nth transmissive holes 191-N are arranged. For example, the first area Al of the black matrix 190 may include, depending on the distance from the virtual boundary line BL, a first unit area A1a where the first transmissive holes 191-1 are arranged, a second unit area A1b where the second transmissive holes 191-2 are arranged, a third unit area A1c where the third transmissive holes 191-3 are arranged, and a fourth unit area A1d where the fourth transmissive holes 191-4 are arranged. The second to fourth areas A2 to A4 may also include a plurality of unit areas.

Additionally, the first transmissive holes 191-1 may be arranged along the virtual boundary line BL, and the second transmissive holes 191-2 may be arranged along the arrangement of the first transmissive holes 191-1. Also, the third transmissive holes 191-3 may be arranged along the arrangement of the second transmissive holes 191-2, and the fourth transmissive holes 191-4 may be arranged along the arrangement of the third transmissive holes 191-3. Considering this arrangement relationship, the N^{th} transmissive holes 191-N may be arranged along the arrangement of the (N-1)^{th} transmissive holes 191-N-1.

Accordingly, the display device according to the third aspect, like the display device according to the second aspect, may significantly reduce the possibility of stains forming near the virtual boundary line BL and also reduce the reflection visibility.

The display device according to the present disclosure may prevent or minimize the possibility of stain occurring depending on the side viewing angle by forming the area of the first transmissive hole 191-1 disposed along the virtual boundary line BL to be larger than that of the other transmissive holes 191.

In addition, the display device according to the present disclosure may reduce the reflection visibility at the side viewing angle by reducing the size of the transmissive hole far from the virtual boundary line BL. Accordingly, the display device according to the present disclosure may improve the display quality without separate compensation for the luminance difference and enables low-power operation of the display device, so that the display device may be improved to meet requirements such as low power consumption and high efficiency.

In addition, the display device according to the present disclosure may improve the design freedom of the display device by adjusting the size and interval of the transmissive holes 191 of the black matrix 190.

The display device according to an aspect of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an e-book, a portable multimedia player (PMP), a personal digital assistant (PDA), an MP3 player, a mobile medical device, a desktop PC, a laptop PC, a netbook computer, a workstation, a navigation, a vehicle display device, a theater display device, a television, a wallpaper device, a signage device, a game device, a notebook, a monitor, a camera, a camcorder, and home appliances. Also, the display device according to one or more aspects of the present disclosure may be applied to an inorganic light-emitting lighting device.

A display device according to one or more aspects of the present disclosure may be described as follows.

A display device according to one or more aspects of the present disclosure may include: a substrate; a plurality of light-emitting elements arranged in each of a plurality of transfer areas on the substrate; and a black matrix having a plurality of transmissive holes each corresponding to one of the plurality of light-emitting elements, wherein the plurality of transfer areas may include a first transfer area and a second transfer area arranged adjacent to each other, the black matrix may include a first area corresponding to the first transfer area and a second area corresponding to the second transfer area, the first area and the second area may be arranged adjacent to each other based on a virtual boundary line, the first area may include a first transmissive hole disposed at a first distance from the virtual boundary line and a second transmissive hole disposed at a second distance from the virtual boundary line, and a size of the first transmissive hole may be larger than a size of the second transmissive hole.

In the display device according to one or more aspects of the present disclosure, the second distance may be larger than the first distance.

In the display device according to one or more aspects of the present disclosure, the first area may include a third transmissive hole disposed at a third distance larger than the second distance based on the virtual boundary line, and a size of the third transmissive hole may be smaller than the size of the second transmissive hole.

In the display device according to one or more aspects of the present disclosure, an interval between the first transmissive hole in the first area and a first transmissive hole in the second area disposed adjacent to each other is smaller than a first interval between the first and second transmissive holes disposed in the first area.

In the display device according to one or more aspects of the present disclosure, the first interval may be smaller than a second interval between the second and third transmissive holes disposed in the first area.

In the display device according to one or more aspects of the present disclosure, an interval between the first transmissive hole and the second transmissive hole may be different from an interval between the second transmissive hole and the third transmissive hole.

In the display device according to one or more aspects of the present disclosure, a center of the light-emitting element disposed to correspond to the first transmissive hole may be spaced apart from a center of the first transmissive hole.

In the display device according to one or more aspects of the present disclosure, a distance between the virtual boundary line and the light-emitting element disposed adjacent to the virtual boundary line in the first transfer area may be different from a distance between the virtual boundary line and the light-emitting element disposed adjacent to the virtual boundary line in the second transfer area.

In the display device according to one or more aspects of the present disclosure, the light-emitting element disposed adjacent to the virtual boundary line in the first transfer area may be disposed at a first transfer distance, the light-emitting element disposed adjacent to the virtual boundary line in the second transfer area may be disposed at a second transfer distance, and a sum of the first transfer distance and the second transfer distance may be larger than a distance from a center of the first transmissive hole in the first area to a center of a first transmissive hole in the second area.

In the display device according to one or more aspects of the present disclosure, the transmissive holes arranged in the black matrix may have an area that becomes smaller as a distance from the virtual boundary line increases.

In the display device according to one or more aspects of the present disclosure, as a distance from the virtual boundary line increases, the transmissive holes arranged in the black matrix have an area that becomes smaller and then becomes constant.

In the display device according to one or more aspects of the present disclosure, an interval between the transmissive holes arranged in the black matrix increases as a distance from the virtual boundary line increases.

In the display device according to one or more aspects of the present disclosure, as a distance from the virtual boundary line increases, an interval between the transmissive holes arranged in the black matrix may become larger and then maintain constant.

In the display device according to one or more aspects of the present disclosure, a plurality of the first transmissive holes may be arranged adjacently along the virtual boundary line.

In the display device according to one or more aspects of the present disclosure, the plurality of light-emitting elements disposed in the first transfer area may be arranged to be spaced apart at predetermined intervals along a first direction and a second direction, and a portion of a first electrode electrically connected to the light-emitting element may overlap with a space between a side of the transmissive hole and one side of the light-emitting element in a third direction.

In the display device according to one or more aspects of the present disclosure, the plurality of transmissive holes may be arranged to be rotationally symmetric with respect to an intersection point P where the virtual boundary lines intersect.

In the display device according to one or more aspects of the present disclosure, the light-emitting element may be an inorganic light-emitting diode.

In the display device according to one or more aspects of the present disclosure, a portion of the light-emitting element disposed to correspond to the third transmissive hole may overlap with the black matrix in a third direction.

The display device according to one or more aspects of the present disclosure may further include: an insulating layer disposed on the substrate; a first electrode and a contact electrode disposed on the insulating layer; a second electrode disposed on the light-emitting element; and a passivation layer covering the first electrode, wherein the light-emitting element is disposed on the first electrode.

The display device according to one or more aspects of the present disclosure may further include a plurality of bank patterns disposed between the insulating layer and the first electrode.

The display device according to one or more aspects of the present disclosure may further include a plurality of connection wires disposed between the substrate and the insulating layer, and a pixel driving circuit connected to the plurality of connection wires, wherein the plurality of connection wires may be electrically connected to the first electrode and the contact electrode.

In the display device according to one or more aspects of the present disclosure, the pixel driving circuit may be a driving driver.

In the display device according to one or more aspects of the present disclosure, a plurality of second electrodes may be arranged to be spaced apart from each other in each pixel row, and each of the plurality of second electrodes may be electrically connected to the contact electrode.

The display device according to one or more aspects of the present disclosure may further include a solder pattern disposed in the first opening hole to electrically connect the first electrode and the light-emitting element.

A display device according to one or more aspects of the present disclosure may include: a substrate; a plurality of light-emitting elements arranged in each of a plurality of transfer areas on the substrate; and a black matrix having a plurality of transmissive holes each corresponding to one of the plurality of light-emitting elements, wherein the plurality of transfer areas may include a first transfer area and a second transfer area arranged adjacent to each other based on a virtual boundary line, the black matrix may include a first area corresponding to the first transfer area and a second area corresponding to the second transfer area, and the transmissive holes arranged in the first area may have a size that becomes smaller as a distance from the virtual boundary line increases.

In the display device according to one or more aspects of the present disclosure, the area of the transmissive hole may decrease as a distance from the intersection point P to the edge of a region of the black matrix increases.

In the display device according to one or more aspects of the present disclosure, with respect to the intersection point, the light emitting elements may be arranged non-rotationally symmetrically, and the transmissive holes may be arranged rotationally symmetrical.

The objects to be achieved by the present disclosure, the means for achieving the objects, and effects of the present disclosure described above do not specify essential features of the claims, and thus, the scope of the claims is not limited to the disclosure of the present disclosure.

Although the aspects of the present disclosure have been described in more detail with reference to the accompanying drawings, the present disclosure is not limited thereto and may be embodied in many different forms without departing from the technical concept of the present disclosure. Therefore, the aspects disclosed in the present disclosure are provided for illustrative purposes only and are not intended to limit the technical concept of the present disclosure. The scope of the technical concept of the present disclosure is not limited thereto. Thus, it is intended that the present disclosure covers the modifications and variations of the aspects provided they come within the scope of the appended claims and their equivalents.

What is claimed is:

1. A display device comprising:
a substrate;
a plurality of light-emitting elements arranged in each of a plurality of transfer areas on the substrate; and
a black matrix having a plurality of transmissive holes each corresponding to one of the plurality of light-emitting elements,
wherein the plurality of transfer areas include a first transfer area and a second transfer area arranged adjacent to each other,
the black matrix includes a first area corresponding to the first transfer area and a second area corresponding to the second transfer area,
the first area and the second area are arranged adjacent to each other based on a virtual boundary line,
the first area includes a first transmissive hole disposed at a first distance from the virtual boundary line and a second transmissive hole disposed at a second distance from the virtual boundary line, and
a size of the first transmissive hole is larger than a size of the second transmissive hole.

2. The display device of claim 1, wherein the second distance is larger than the first distance.

3. The display device of claim 2, wherein the first area includes a third transmissive hole disposed at a third distance larger than the second distance based on the virtual boundary line, and
a size of the third transmissive hole is smaller than the size of the second transmissive hole.

4. The display device of claim 3, wherein an interval between the first transmissive hole in the first area and a first transmissive hole in the second area disposed adjacent to each other is smaller than a first interval between the first and second transmissive holes disposed in the first area.

5. The display device of claim 4, wherein the first interval is smaller than a second interval between the second and third transmissive holes disposed in the first area.

6. The display device of claim 3, wherein an interval between the first transmissive hole and the second transmissive hole is different from an interval between the second transmissive hole and the third transmissive hole.

7. The display device of claim 1, wherein a center of the light-emitting element disposed to correspond to the first transmissive hole is spaced apart from a center of the first transmissive hole.

8. The display device of claim 1, wherein a distance between the virtual boundary line and the light-emitting element disposed adjacent to the virtual boundary line in the first transfer area is different from a distance between the virtual boundary line and the light-emitting element disposed adjacent to the virtual boundary line in the second transfer area.

9. The display device of claim 1, wherein the light-emitting element disposed adjacent to the virtual boundary line in the first transfer area is disposed at a first transfer distance,
the light-emitting element disposed adjacent to the virtual boundary line in the second transfer area is disposed at a second transfer distance, and
a sum of the first transfer distance and the second transfer distance is larger than a distance from a center of the first transmissive hole in the first area to a center of a first transmissive hole in the second area.

10. The display device of claim 1, wherein the transmissive holes arranged in the black matrix have an area that becomes smaller as a distance from the virtual boundary line increases.

11. The display device of claim 1, wherein as a distance from the virtual boundary line increases, the transmissive holes arranged in the black matrix have an area that becomes smaller and then becomes constant.

12. The display device of claim 1, wherein an interval between the transmissive holes arranged in the black matrix increases as a distance from the virtual boundary line increases.

13. The display device of claim 1, wherein as a distance from the virtual boundary line increases, an interval between the transmissive holes arranged in the black matrix becomes larger and then maintains constant.

14. The display device of claim 1, wherein a plurality of the first transmissive holes are arranged adjacently along the virtual boundary line.

15. The display device of claim 1, wherein the plurality of light-emitting elements disposed in the first transfer area are arranged to be spaced apart at predetermined intervals along a first direction and a second direction, and
a portion of a first electrode electrically connected to each of the plurality of light-emitting elements overlaps with a space between a side of the transmissive hole and one side of connected light-emitting element in a third direction.

16. The display device of claim 1, wherein the plurality of transmissive holes are arranged to be rotationally symmetric with respect to an intersection point where the virtual boundary lines intersect.

17. The display device of claim 1, wherein the light-emitting element is an inorganic light emitting diode.

18. The display device of claim 3, wherein a portion of the light-emitting element disposed to correspond to the third transmissive hole overlaps the black matrix in a third direction.

19. The display device of claim 1, further comprising:
an insulating layer disposed on the substrate;
a plurality of first electrodes and a contact electrode disposed on the insulating layer;
a second electrode disposed on the plurality of light-emitting elements; and
a passivation layer covering the plurality of first electrodes,
wherein the plurality of light-emitting elements are disposed on the plurality of first electrodes.

20. The display device of claim 19, further comprising:
a plurality of connection wires disposed between the substrate and the insulating layer, and
a pixel driving circuit connected to the plurality of connection wires,
wherein the plurality of connection wires are electrically connected to the plurality of first electrodes and the contact electrode.

21. A display device comprising:
a substrate;
a plurality of light-emitting elements arranged in each of a plurality of transfer areas on the substrate; and
a black matrix having a plurality of transmissive holes each corresponding to one of the plurality of light-emitting elements,
wherein the plurality of transfer areas include a first transfer area and a second transfer area arranged adjacent to each other based on a virtual boundary line,
wherein the black matrix includes a first area corresponding to the first transfer area and a second area corresponding to the second transfer area, and
wherein the transmissive holes arranged in the first area have a size that becomes smaller as a distance from the virtual boundary line increases.

22. A display device comprising:
a substrate;
a plurality of light-emitting elements arranged in each of a plurality of transfer areas on the substrate; and
a black matrix having a plurality of transmissive holes each corresponding to one of the plurality of light-emitting elements,
wherein the plurality of transfer areas include a first transfer area and a second transfer area arranged adjacent to each other,
the black matrix includes a first area corresponding to the first transfer area and a second area corresponding to the second transfer area,
the first area and the second area are arranged adjacent to each other based on a virtual boundary line,
the first area includes a first transmissive hole disposed at a first distance from the virtual boundary line, a second transmissive hole disposed at a second distance from the virtual boundary line, and a third transmissive hole disposed at a third distance from the virtual boundary line, and
a size of the first transmissive hole is larger than a size of the second transmissive hole, and the size of the second transmissive hole is larger than a size of the third transmissive hole.

23. The display device of claim 22, wherein the second distance is larger than the first distance, and the third distance is larger than the second distance.

24. The display device of claim 23, wherein an interval between the first transmissive hole and the second transmissive hole is different from an interval between the second transmissive hole and the third transmissive hole.
